(19) United States
(12) Patent Application Publication
(10) Pub. No.: US 2008/0211042 A1
(43) Pub. Date: Sep. 4, 2008

(54) METHOD FOR MANUFACTURING SEMICONDUCTOR DEVICE, AND SEMICONDUCTOR DEVICE

(75) Inventor: Teruo TAKIZAWA, Matsumoto-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/038,908

(22) Filed: Feb. 28, 2008

(30) Foreign Application Priority Data
Feb. 28, 2007 (JP) 2007-048616
Jan. 23, 2008 (JP) 2008-012292

(51) Int. Cl. H01L 21/02; H01L 29/84

(52) U.S. Cl. 257/415; 438/50; 257/E21.002; 257/E29.324

(57) ABSTRACT

To provide a method for manufacturing a semiconductor device and a semiconductor device manufactured by the method. In the method, a movable portion formed on a semiconductor substrate can be released by etching an insulation layer in a shorter time and more readily controlling the etching amount in a section direction of the insulation layer.

A method for manufacturing a semiconductor device 10 includes: a step of forming a structure 30 on an insulation layer 14 formed on a semiconductor substrate 14, the structure including a piezoelectric layer 22, a first electrode 20, and a second electrode 24; a step of exposing a section of the insulation layer 14 by dicing the semiconductor device 10; and a step of removing the insulation layer 14 from the exposed section so as to release a movable portion 30b of the structure 30 while a fixing portion 30a of the structure 30 is fixed on the insulation layer 14.

### TECHNICAL FIELD

Several aspects of the present invention relate to a method for manufacturing a semiconductor device, and a semiconductor device.

### BACKGROUND TECHNOLOGY

In recent years, sensors, resonators, communications devices and the like have drawn attention that are provided with a MEMS element on a semiconductor substrate by taking advantage of MEMS (Micro Electro Mechanical System) technology. Most of these devices include a movable structure on the semiconductor substrate with a supporting portion interposed therebetween, and play a role of a converter (transducer) to convert an electrical signal into a mechanical vibration or a mechanical vibration to an electrical signal.

In a manufacturing process of such devices including the MEMS element, after an insulation layer and a structure are formed on a semiconductor substrate, a part of the insulation layer between the semiconductor substrate and the structure is removed to leave a supporting portion, and set a movable portion free (release a movable portion) of the structure. As one of methods to remove a part of the insulation layer, a method is described in Patent Document 1 in which the semiconductor substrate is etched from a side adjacent to a lower surface thereof so as to expose a lower surface of the insulation layer and then the insulation layer is etched from the lower surface. As another method, a method is described in Patent document 2 in which the insulation layer is etched from an exposed part on an upper surface thereof.

### [Patent Document 1] Japanese Unexamined Patent Application Publication No. 2005-337956.

### [Patent Document 2] Japanese Unexamined Patent Application Publication No. 2006-95632.

### DISCLOSURE OF INVENTION

### Problems to be Solved

Problems to be solved are that a total time taken for etching becomes long when a substrate and the like are etched before etching the insulation layer, and it is difficult to control an etching amount in the section direction of the insulation layer so as not to vary the dimension and shape of a portion left as the supporting portion when the insulation layer is wet etched from an exposed part on upper surface thereof.

### Means to Solve the Problems

According to the invention, it is characterized in that a method for manufacturing a semiconductor device includes: a step of forming a structure including a piezoelectric layer, a first electrode, and a second electrode on an insulation layer provided on a semiconductor substrate of a semiconductor device, the substrate including a semiconductor integrated circuit; a step of exposing a section of the insulation layer by dicing the semiconductor device; and a step of removing the insulation layer from the exposed section by selectively etching so as to release a movable portion of the structure while a fixing portion of the structure is fixed on the insulation layer.

According to the method, the step of cutting at least a part of the insulation layer to expose the section of the insulation layer is carried out before the step of removing a portion, overlapping with the movable portion of the structure, of the insulation layer by selective etching. Accordingly, the insulation layer can be removed from not only the exposed portion of the upper surface thereof but also the exposed section in etching the insulation layer. As a result, etching the insulation layer can be carried out in a shorter time.

In the method for manufacturing a semiconductor device, the step of forming the structure may include: a step of forming a semiconductor layer and a second insulation layer on the insulation layer in order; a step of forming the first electrode, the piezoelectric layer, and the second electrode on the second insulation layer in order; and a step of removing at least a part of a portion of each of the semiconductor layer and the second insulation layer so as to form the structure including the semiconductor layer, the second insulation layer, the first electrode, the piezoelectric layer, and the second electrode. The portion does not overlap with any of the first electrode, the piezoelectric layer, and the second electrode.

According to the method, the structure is configured by including the semiconductor layer and the second insulation layer in addition to the first electrode, the piezoelectric layer, and the second electrode, thereby enabling the thickness of the structure to be thick. The thickness of the structure also can be changed by changing the thickness of the semiconductor layer or the second insulation layer. Changing the thickness of the structure can change the resonance frequency of the structure, enabling the design freedom of the semiconductor device to be enhanced.

In the method for manufacturing a semiconductor device further may include a step of forming the semiconductor integrated circuit on the semiconductor substrate before the step of exposing the section of the insulation layer.

According to the method, the semiconductor device including the structure and the semiconductor integrated circuit in a one-chip manner can be formed, thereby eliminating additional steps of individually mounting the structure and the semiconductor integrated circuit. In addition, forming the structure and the semiconductor integrated circuit on the same substrate allows the semiconductor device to be downsized.

According to the invention, it is characterized in that a method for manufacturing a semiconductor device includes: a step of forming a second insulation layer on a layered body including a semiconductor layer and an insulation layer that are layered on a semiconductor substrate of a semiconductor device, the substrate including a semiconductor integrated circuit; a step of forming a first electrode, a piezoelectric layer, and a second electrode on the second insulation layer in order; a step of removing at least a part of a portion of each of the semiconductor layer and the second insulation layer so as to form a structure including the semiconductor layer, the second insulation layer, the first electrode, the piezoelectric layer, and the second electrode, wherein the portion does not overlap with any of the first electrode, the piezoelectric layer, and the second electrode; a step of exposing a section of the insulation layer by dicing the semiconductor device; and a step of removing the insulation layer from the exposed section by selectively etching so as to release a movable portion of the structure while a fixing portion of the structure remains on the insulation layer.

According to the method, the use of the layered body allows the semiconductor device including the structure to be more efficiently manufactured. In addition, the use of the layered body allows the thickness of the semiconductor layer to be thicker, thereby enabling the thickness of the structure to be thicker. As a result, the design freedom of the semiconductor device can be further enhanced. Further, dicing the semiconductor device before releasing the structure can prevent the mechanical vibration characteristics of the structure from being influenced by dust.

The method for manufacturing a semiconductor device further may include a step of forming the semiconductor integrated circuit on the layered body before the step of exposing the section of the insulation layer.

According to the method, the use of the layered body allows the semiconductor device including the structure and the semiconductor integrated circuit in a one-chip manner to be more efficiently manufactured.

In the method for manufacturing a semiconductor device, at least a part of the insulation layer excluding the fixing portion of the structure may be cut in the step of exposing the section of the insulation layer.

According to the method, the portion, overlapping with the fixing portion of the structure, of the insulation layer, i.e., the portion left, is not cut. Thus, the section of the portion is not exposed. Because of this, the insulation layer is not removed from the section of the portion left, in etching the insulation layer. As a result, the removing amount of the insulation layer in the section direction can be more readily controlled without varying the dimension and the shape of the portion left.

In the method for manufacturing a semiconductor device, the layered body may include a protective layer positioned between the insulation layer and the semiconductor layer; and a part of the protective layer is positioned in a surface, positioned between the semiconductor substrate and the movable portion of the structure, of the movable portion of the structure, after the step of removing the insulation layer by selectively etching.

According to the method, though the protective layer makes contact with the semiconductor substrate, in the event of the movable portion of the structure being pulled toward the semiconductor substrate side, the movable portion of the structure and the semiconductor substrate can be prevented from being touched each other and electrically conducted. In addition, the protective layer formed small can prevent the protective layer from adhering to the semiconductor substrate in a case where the protective layer makes contact with the semiconductor substrate.

The method for manufacturing a semiconductor device may further include a step of forming a protective layer on a surface, positioned between the semiconductor substrate and the movable portion of the structure, of the movable portion of the structure, after the step of removing the insulation layer selectively etching.

According to the method, though the protective layer makes contact with the semiconductor substrate, in the event of the movable portion of the structure being pulled toward the semiconductor substrate side, the movable portion of the structure and the semiconductor substrate can be prevented from being touched each other and electrically conducted. In addition, the protective layer formed small can prevent the protective layer from adhering to the semiconductor substrate in a case where the protective layer makes contact with the semiconductor substrate.

According to the invention, it is characterized in that a semiconductor device is manufactured by the method for manufacturing a semiconductor device described above.

As a result, the semiconductor device having good productivity can be provided because etching the insulation layer can be carried out in shorter time and the etching amount in the section direction of the insulation layer can be more readily controlled when the structure is released.

### BRIEF DESCRIPTION OF THE DRAWINGS

FIG. 1 is a view showing the schematic configuration of a semiconductor device according to a first embodiment.

FIG. 2 is a sectional view taken along the line A-A in FIG. 1.

FIG. 3 is a view explaining a method for manufacturing the semiconductor device according to the first embodiment.

FIG. 4 is a view explaining the method for manufacturing the semiconductor device according to the first embodiment.

FIG. 5 is a view showing the schematic configuration of a semiconductor device according to a second embodiment.

FIG. 6 is a view explaining a method for manufacturing the semiconductor device according to the second embodiment.

FIG. 7 is a view explaining the method for manufacturing the semiconductor device according to the second embodiment.

FIG. 8 is a view explaining the modification of the method for manufacturing the semiconductor device according to the first embodiment.

FIG. 9 is a view explaining the modification of the method for manufacturing the semiconductor device according to the first embodiment.

FIG. 10 is a view explaining the modification of the method for manufacturing the semiconductor device according to the first embodiment.

### EXPLANATION OF NUMERALS

10: semiconductor device 12: semiconductor substrate 14: insulation layer 14a: insulation layer 16: semiconductor layer 18: second insulation layer 20: first electrode 22: piezoelectric layer 24: second electrode 30: structure 30a: fixing portion 30b: movable portion 40: wafer 50: semiconductor device 52: first electrode 54: piezoelectric layer 56: second electrode 58: structure 60: semiconductor device 62: piezoelectric layer 64: first electrode 66: second electrode 68: structure 70: semiconductor device 72: protective layer 74: structure 74b: movable portion 100: semiconductor device 102: semiconductor substrate 104: resonator 106: oscillation circuit 108: AD/DA converter 110: flash memory 112: CPU 114: power supply portion 116: SRAM 120: CMOS integrated circuit portion La1: scribe line La2: scribe line Lb: scribe line

### DESCRIPTION OF THE PREFERRED EMBODIMENTS

The embodiments of the invention will now be described with reference to the accompanying drawings. In each referred drawing, a scale size of each member may be different so as to readily show the configuration. In each referred drawing, details of wiring lines and connecting portions are also omitted.

### First Embodiment

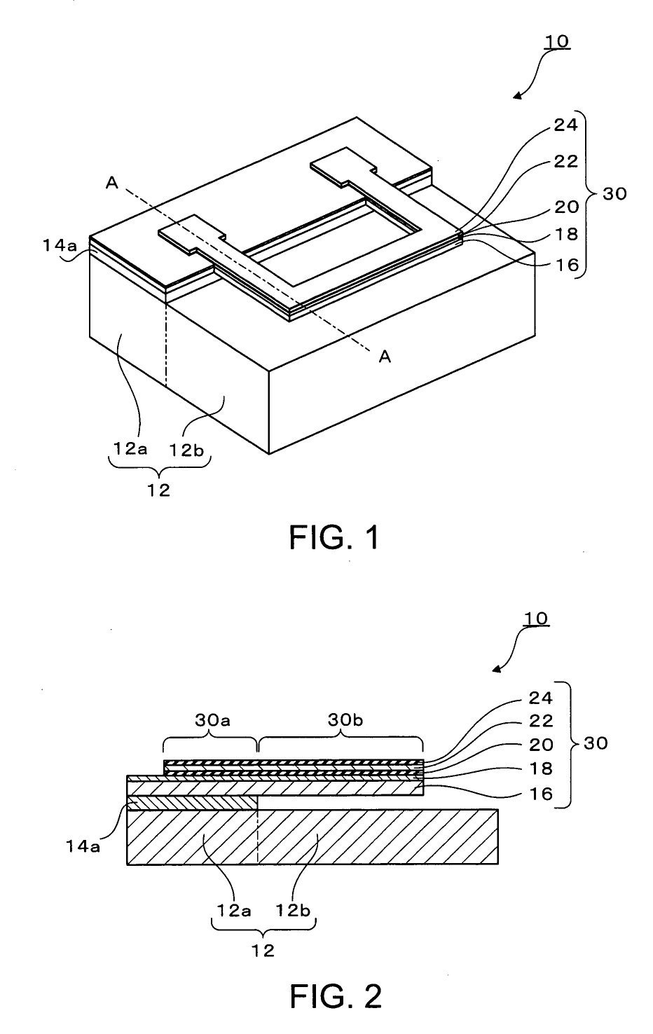

First, the configuration of a semiconductor device according to a first embodiment will be described with reference to the drawings. FIG. 1 is a view showing the schematic configuration of the semiconductor device according to the first embodiment. FIG. 2 is a sectional view taken along the line A-A in FIG. 1.

A semiconductor device 10 of the first embodiment includes a semiconductor substrate 12, an insulation layer 14a, and a structure 30 as shown in FIG. 1 and FIG. 2.

The semiconductor substrate 12 includes a first section 12a and a second section 12b that make contact with each other. The material of the semiconductor substrate 12 is, for example, silicon. The insulation layer 14a is formed on the first section 12a of the semiconductor substrate 12. The insulation layer 14a remains after removing a portion of an insulation layer 14 (which will described later) formed on the semiconductor substrate 12. The portion is overlapped with the second section 12b. The material of the insulation layer 14a (insulation layer 14) is not particularly limited as long as it can be selectively etched. The material of the insulation layer 14a (insulation layer 14) is, for example, SiO₂. The structure 30 is supported on the insulation layer 14a and lies astride the first section 12a and the second section 12b of the semiconductor substrate 12. The structure 30 includes a fixing portion 30a and a movable portion 30b (see FIG. 2). The fixing portion 30a is positioned so as to overlap on the insulation layer 14a in a region of the first section 12a of the semiconductor substrate 12. The movable portion 30b is positioned so as to be separated from the upper surface of the semiconductor substrate 12 with a gap corresponding to the thickness of the insulation layer 14a, in a region of the second section of the semiconductor substrate 12.

The structure 30 is composed of a semiconductor layer 16, a second insulation layer 18, a first electrode 20, a piezoelectric layer 22, and a second electrode 24. The structure 30 configured so as to include the semiconductor layer 16 and the insulation layer 18 can thicken the thickness of the structure 30. The thickness of the structure 30 also can be changed by changing the thickness of the semiconductor layer 16 or the second insulation layer 18. Since changing the thickness of the structure 30 can change the resonance frequency of the structure 30, this configuration can enhance the design freedom of a semiconductor device. The structure 30 may be configured so as not to include the semiconductor layer 16 and the second insulation layer 18.

The semiconductor layer 16 is formed so that a portion thereof included in the fixing portion 30a is fixed on the insulation layer 14a while a portion thereof included in the movable portion 30b is faced to and separated from the semiconductor substrate 12 with a gap interposed therebetween. The semiconductor 16 is also formed so that the portion thereof included in the movable portion 30b overlaps with all of the first electrode 20, the piezoelectric layer 22 and the second electrode 24 that are formed above thereof. The material of the semiconductor layer 16 is, for example, monocrystalline silicon. The material of the semiconductor layer 16 may be polycrystalline silicon.

The second insulation layer 18 is formed so as to cover the upper surface of the semiconductor layer 16. The material of the second insulation layer 18 is, for example, SiO₂. The first electrode 20 is formed on the second insulation layer 18, and at least one end thereof overlaps with the insulation layer 14a. In the embodiment, the first electrode 20 is formed in a reversed C-shape and so that both ends thereof overlap with the insulation layer 14a. The material of the first electrode 20 is, for example, platinum. Examples of the material of the first electrode 20 may include titanium, gold, molybdenum, aluminum, nickel, titanium nitride, iridium, ruthenium, and a multi-layered film mainly composed of these materials, other than platinum.

The piezoelectric layer 22 is formed so that at least one portion thereof overlaps on the first electrode 20 and at least one end thereof overlaps with the insulation layer 14a. In the embodiment, the piezoelectric layer 22 is formed so as to cover the upper surface of the first electrode 20. The material of the piezoelectric layer 22 is, for example, lead zirconium titanate. Example of the material of the piezoelectric layer 22 may include quartz, lithium niobate, barium titanate, lead titanate, lead niobate, polyvinylidene fluoride, aluminum nitride, zinc oxide, and a mixture mainly composed of these materials. The second electrode 24 is formed so as to cover the upper surface of the piezoelectric layer 22. The material of the second electrode 24 is, for example, platinum. The material of the second electrode 24 may be titanium.

The semiconductor device 10 may also be formed by using a layered body (SOI substrate) including the insulation layer 14 and the semiconductor layer 16 that are formed on the semiconductor substrate 12. The use of a SOI substrate allows a semiconductor device including a structure to be more efficiently manufactured. The use of the SOI substrate also allows the thickness of the semiconductor layer 16 to become thicker as compared to a case in which the semiconductor layer 16 is formed by a semiconductor process. Therefore, the use of the SOI substrate allows the thickness of the structure 30 to become thicker, thereby enabling the design freedom of a semiconductor device to be further enhanced.

The semiconductor device 10 can be used, for example, as a resonator. In this case, the piezoelectric layer 22 is deformed by applying a small electrical signal between the first electrode 20 and the second electrode 24. As a result, the movable portion 30b of the structure 30 vibrates. The semiconductor device 10 can also be used as a sensor by converting a deformation of the movable portion 30b of the structure 30 due to an applied external force into an electrical signal in the piezoelectric layer 22, and taking out the electrical signal from the first electrode 20 and the second electrode 24.

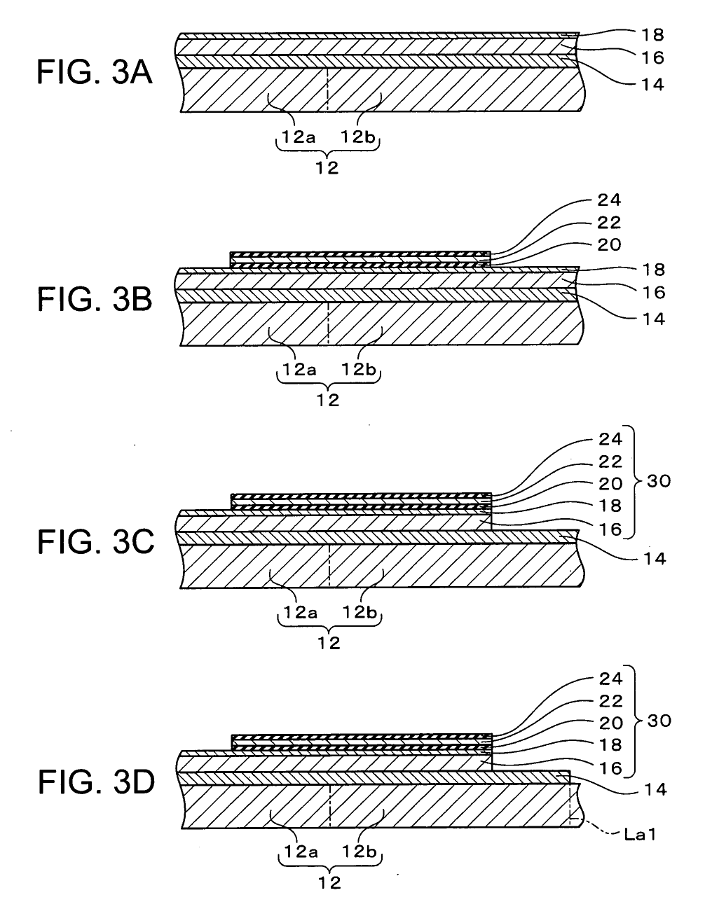

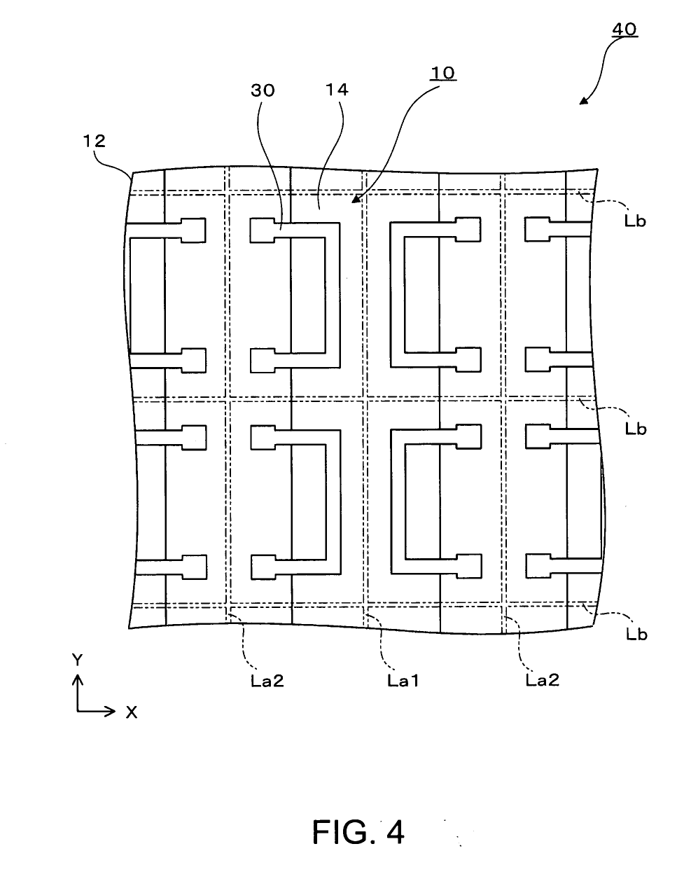

Next, a method for manufacturing the semiconductor device having the configuration described above with reference to the drawings. FIGS. 3 and 4 are diagrams explaining a method for manufacturing the semiconductor device according to the first embodiment.

In the method for manufacturing the semiconductor device 10 according to the first embodiment, at first, a multi-layered body (SOI substrate) including the insulation layer 14 and the semiconductor layer 16 that are formed on the semiconductor substrate 12 is prepared as shown in FIG. 3(a). The thickness of the semiconductor substrate 12 is, for example, from 300 μm to 600 μm. The thickness of the insulation layer 14 is, for example, 4 μm. The thickness of the semiconductor layer 16 is, for example, 40 μm. Instead of using the SOI substrate, the insulation layer 14 may be formed on the semiconductor substrate 12 and the semiconductor layer 16 may be formed on the insulation layer 14. Here, when the semiconductor device 10 is formed, the first section 12a is defined as a region in which the insulation layer 14a remains so as to support the fixing portion 30a of the structure 30 in the semiconductor substrate 12 while the second section 12b is defined as a region in which the insulation layer 14 is removed so as to release the movable portion 30b of the structure 30 in the semiconductor substrate 12.

Next, the second insulation layer 18 is formed on the semiconductor layer 16. The second insulation layer 18 is formed by applying a thermal oxidation method, for example.

Then, as shown in FIG. 3(b), the first electrode 20 is formed on the second insulation layer 18 so as to lie astride the first section 12a and the second section 12b of the semiconductor substrate 12. The first electrode 20 is formed, for example, by forming an electrode film by applying a sputtering method, and then patterning the film to a predetermined shape. Subsequently, the piezoelectric layer 22 is formed so as to overlap with at least a part of the first electrode 20, and lie astride the first section 12a and the second section 12b of the semiconductor substrate 12. The piezoelectric layer 22 is formed, for example, by forming a piezoelectric film by applying a sol-gel method, and then patterning the film to a predetermined shape. The piezoelectric layer 22 may be formed by forming a piezoelectric film by applying a reactive sputtering method, and then patterning the film to a predetermined shape. Then, the second electrode 24 is formed so as to cover the piezoelectric layer 22. The second electrode 24 is formed, for example, by forming an electrode film by applying a sputtering method, and then patterning the film to a predetermined shape. In the embodiment, the first electrode 20, the piezoelectric layer 22, and the second electrode 24 are patterned into a reversed C-shape as an example of the predetermined shape (see FIG. 1).

Next, as shown in FIG. 3(c), at least a part of each portion of the semiconductor layer 16 and the second insulation layer 18 is removed. Each portion does not overlap with any of the first electrode 20, the piezoelectric layer 22, and the second electrode 24. In the embodiment, a portion excluding a portion overlapping with the region of the first section 12a of the semiconductor substrate 12 and the first electrode 20 is removed from each of the semiconductor layer 16 and the second insulation layer 18 (see FIG. 1). The part of each of the semiconductor layer 16 and the insulation layer 18 is removed by, for example, applying a photolithographic method. Consequently, the structure 30 is formed that is composed of the semiconductor layer 16, the second insulation layer 18, the first electrode 20, the piezoelectric layer 22, and the second electrode 24 on and above the insulation layer 14. As a result, an upper surface of the insulation layer 14 that excludes a portion thereof overlapping with the semiconductor layer 16 and is in the region of the second section 12b of the semiconductor substrate 12, is exposed. While not shown in the figure, an etching protective film may be formed with silicon nitride, a photoresist, or the like so as to cover a portion excluding the exposed portion of the insulation layer 14. Here, in the structure 30, a portion thereof overlapping with the region of the first section 12a of the semiconductor substrate 12 serves as the fixing portion 30a while another portion thereof overlapping with the region of the first section 12b of the semiconductor substrate 12 serves as the movable portion 30b (see FIG. 2).

As a result of steps described above, as shown in FIG. 4, the semiconductor device 10 in which the structure 30 is formed is arranged in a plurality of numbers on a wafer 40 composed of the semiconductor substrate 12. In the embodiment, the plurality the semiconductor devices 10 are arranged so that the exposed surface of the insulation layer 14 forms a line in each column along the Y-axis direction. The semiconductor devices 10 are also arranged so that a side in which the insulation layer 14 is exposed and a side in which the insulation layer 14 is not exposed are alternately disposed in each row along the X-axis direction. That is, in two columns of semiconductor devices 10 adjacent each other along the Y-axis direction, each side in which the insulation layer 14 is exposed is faced each other, or each side in which the insulation layer 14 is not exposed is faced each other. Here, the side in which the insulation layer 14 is exposed is in the second section 12b of the semiconductor substrate 12. The semiconductor devices 10 on the wafer 40 are singulated into individual devices by being cut along scribe lines La1 and La2 along the Y-axis direction and a scribe line Lb along the X-axis direction in a later step. In this cutting, the semiconductor devices 10 on the wafer 40 are cut by the scribe line La1 between two columns along the Y-axis direction, in which each side in which the insulation layer 14 is exposed is faced and next to each other while by the scribe line La2 between two columns along the Y-axis direction, in which each side in which the insulation layer 14 is not exposed is faced and next to each other.

Next, at least a part of the insulation layer 14 is cut so as to expose the section of the insulating layer 14. Preferably, at least a part of a portion of the insulation layer 14 is cut, the portion excluding a portion thereof overlapping with the region of the first section 12a of the semiconductor substrate 12. In the embodiment, the insulation layer 14 is cut along the scribe line La1 by using a dicing saw or laser. As a result, as shown in FIG. 3(d), the section, cut along the scribe line La1, of the insulation layer 14 is exposed. That is, the section is exposed that is of a portion of the insulation layer 14 in the second section 12b of the semiconductor substrate 12. In this step, it is noted that the semiconductor substrate is half-cut, but not fully cut off.

Next, a portion, overlapping with the second section 12b of the semiconductor substrate 12, of the insulation layer 14 is removed by wet etching so that the fixing portion 30a of the structure 30 remains and the removable portion 30b of the structure 30 is released. As an etchant, for example, a liquid containing hydrofluoric acid is used. In this etching, the insulation layer 14 can be removed from not only the exposed portion on the upper surface thereof but also the exposed section because the insulation layer 14 is exposed at a part of the upper surface thereof and at the section of the portion cut along the scribe line La1 in the second section 12b. Therefore, the process to remove a part of the insulation layer 14 can be carried out in a shorter time. In addition, the insulation layer 14 is not exposed as the section of a portion thereof in the first section 12a. Thus, the insulation layer 14 is not removed from the section of the portion. Accordingly, the removing amount of the insulation layer 14 in the section direction can be more readily controlled without varying the dimension and the shape of the insulation layer 14 that remains. Consequently, the insulation layer 14a remains so as to support the fixing portion 30a of the structure 30.

Next, the wafer 40, on which the semiconductor devices 10 are arranged, is fully cut off along the scribe lines La1, La2, and Lb shown in FIG. 4 so as to be individually singulated into the semiconductor device 10. As a result, the semiconductor device 10 is provided (see FIG. 1 and FIG. 2).

According to the manner described above, negative effects can be suppressed in that dust produced in dicing sticks on the structure to fluctuate the mechanical vibration characteristics when the singulation is carried out by dicing after releasing of the structure, and the like.

### Second Embodiment

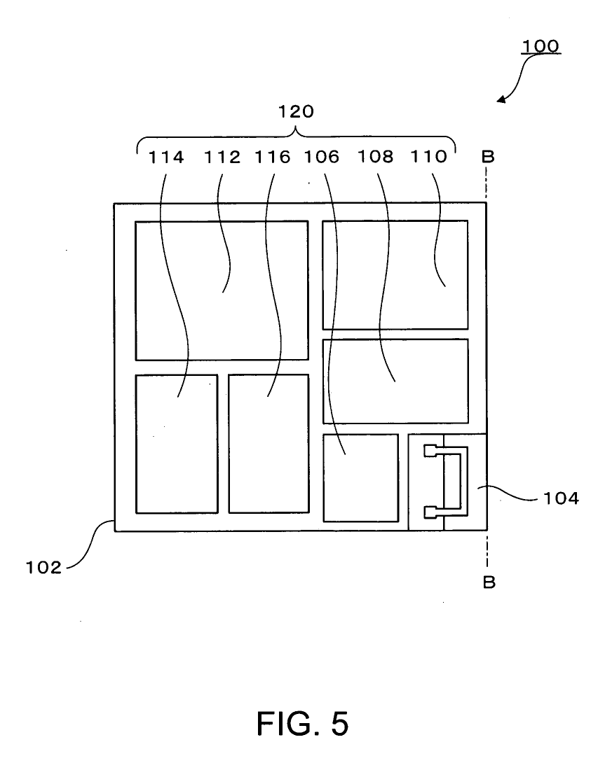

Next, the configuration of a semiconductor device according to a second embodiment will be described with reference to the drawings. The descriptions already explained in the first embodiment are omitted. FIG. 5 is a view showing the schematic configuration of the semiconductor device according to the second embodiment.

A semiconductor device 100 of the second embodiment is a one-chip microcomputer and includes the semiconductor device of the first embodiment as a resonator. The semiconductor device 100 includes a resonator 104, and a CMOS integrated circuit portion 120 serving as a semiconductor integrated circuit that are formed on a semiconductor substrate 102, as exemplarily shown in FIG. 5.

The semiconductor substrate 102 is, for example, a multi-layered body (SOI substrate) including an insulation layer and a semiconductor layer that are layered on a semiconductor substrate. The semiconductor substrate 102 may be formed by layering an insulation layer and a semiconductor layer on a semiconductor substrate. The resonator 104 has the same configuration as that of the semiconductor device of the first embodiment. The resonator 104 is disposed on the semiconductor substrate 102 so that the movable portion side of the structure brings into line with the outer circumference of the semiconductor device 100, for example. In the embodiment, a corner portion including the movable portion of the structure of the resonator 104 is positioned at the corner portion of the outer circumference of the semiconductor device 100. The CMOS integrated circuit portion 120 is composed of an oscillation circuit 106, an AD/DA converter 108, a flash memory 110, a CPU 112, a power supply portion 114, and a SRAM 116.

While not shown in the figure, the semiconductor device 100 includes interlayer insulation layers, wiring layers, and connecting portions other than the elements described above. In addition, necessary wiring lines are provided between each element of the CMOS integrated circuit portion 120, and between the resonator 104 and the CMOS integrated circuit portion 120.

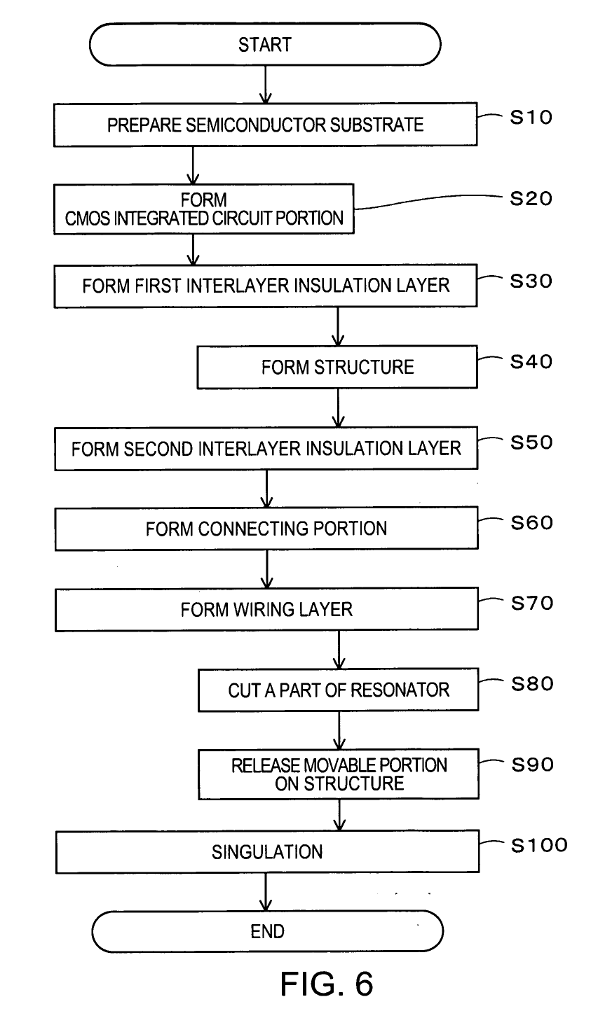

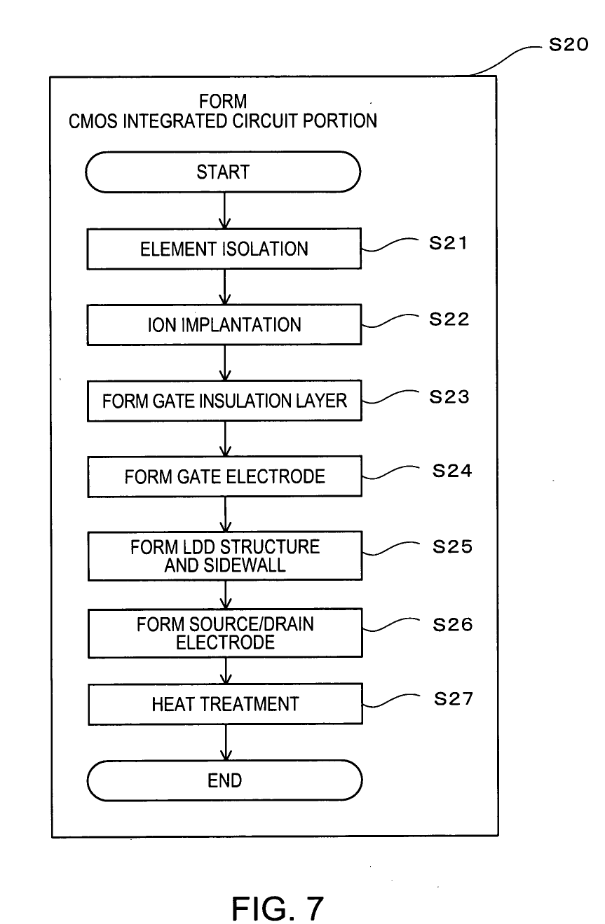

Next, a method for manufacturing the semiconductor device having the configuration described above with reference to the drawings. FIGS. 6 and 7 are diagrams explaining a method for manufacturing the semiconductor device according to the second embodiment.

In the method for manufacturing the semiconductor device 100 according to the second embodiment, at first, the semiconductor substrate 102 of a SOI substrate including an insulation layer and a semiconductor layer that are formed on a semiconductor substrate, is prepared as shown in FIG. 6 (step S10). The semiconductor substrate 102 may be formed by layering an insulation layer and a semiconductor layer on a semiconductor substrate.

Next, the CMOS integrated circuit portion 120 is formed on the semiconductor substrate 102 (step S20). In the embodiment, the step of forming the CMOS integrated circuit portion 120 includes the following steps that are carried out in order, as shown in FIG. 7. The steps are: element isolation (step S21); ion implantation (step S22); forming gate insulation layer (step S23); forming gate electrode (step S24); forming LDD structure and sidewall (step S25); forming source electrode and drain electrode (step S26); and heat treatment (step S27).

Then, as shown in FIG. 6, a first interlayer insulation layer is formed on the semiconductor substrate 102 and the CMOS integrated circuit portion 120 (step S30).

Next, the structure of the resonator 104 is formed (step S40). The structure of the resonator 104 is formed by the method for manufacturing the semiconductor device 10 of the first embodiment up to the step shown in FIG. 3(c). Here, in the semiconductor substrate 102, the semiconductor substrate serving as a base, the insulation layer, and the semiconductor layer correspond respectively to the semiconductor substrate 12, the insulation layer 14, and the semiconductor layer 16 of the semiconductor device 10. In addition, the first interlayer insulation layer corresponds to the second insulation layer 18 of the semiconductor device 10. Therefore, as a result of this step, the upper surface of a portion, excluding a region covered with the semiconductor layer, of the insulation layer of the semiconductor substrate 102 in the region of the resonator 104 is exposed.

Then, as shown in FIG. 6, a second interlayer insulation layer is formed on the CMOS integrated circuit portion 120 and the resonator 104 (step S50). In this step, the second interlayer insulation layer is not formed on the portion, exposed in the step S40, of the insulation layer of the semiconductor substrate 102 in the region of the resonator 104.

Next, connecting portions are formed in the first interlayer insulation layer and the second interlayer insulation layer so as to provide an electrical conduction between upper and lower layers of each interlayer insulation layer (step S60).

Next, a wiring layer is formed on the first interlayer insulation layer and the second interlayer insulation layer (step S70).

Next, a part of the resonator 104 is cut (step S80). The part of the resonator 104 is cut by the method for manufacturing the semiconductor device 10 of the first embodiment in the step shown in FIG. 3(d). In the embodiment, the insulation layer of the semiconductor substrate 102 is cut along the scribe line (line B-B in FIG. 5) of the outer circumference of the semiconductor device 100. The scribe line is brought into line with the movable portion side of the structure of the resonator 104. As a result, the section of a portion, cut along the scribe line, of the insulation layer of the semiconductor substrate 102 is exposed. An etching protective film may be formed with silicon nitride, a photoresist, or the like so as to cover a portion excluding the insulation layer, exposed in the region of the resonator 104, of the semiconductor substrate 102.

According to the manner described above, negative effects can be suppressed in that dust produced in dicing sticks on the structure to fluctuate the mechanical vibration characteristics when the singulation is carried out by dicing after releasing of the structure, and the like.

Next, as shown in FIG. 6, the movable portion of the structure of the resonator 104 is released (step S90).

Then, the wafer on which the semiconductor device 100 is arranged in a plurality of numbers is fully cut off along the scribe line so as to be individually singulated into the semiconductor device 100 (step S100). As a result, the semiconductor device 100 is provided. According to the manufacturing method of the embodiment, the semiconductor device 100 including the resonator 104 and the CMOS integrated circuit portion 120 in a one-chip manner can be fabricated by wafer surface processing, eliminating additional steps for individually mounting the resonator and the integrated circuit portion. In addition, forming the resonator 104 and the CMOS integrated circuit portion 120 on the same substrate allows the semiconductor device 100 to be downsized.

Note that the embodiments of the invention, not limited to the ones described above, can be implemented as follows.

### [First Modification]

In the first embodiment, the step of the singulation of the semiconductor device 10 is carried out after the step of releasing the movable portion 30b of the structure 30 of the semiconductor device 10. However, the invention is not limited to such embodiment. The step of the singulation of the semiconductor device 10 may be carried out before the step of releasing the movable portion 30b of the structure 30 of the semiconductor device 10. According to the steps described above, even though cutting debris and dust are produced from a cut section during the singulation of the semiconductor device 10, the produced cutting debris and dust can be removed without adhering to the structure 30 because etching is carried out in the step of releasing the movable portion 30b of the structure 30.

### [Second Modification]

In the second embodiment, the step of the singulation of the semiconductor device 100 (step S100) is carried out after the step of releasing the movable portion of the structure of the resonator 104 (step S90). However, the invention is not limited to such embodiment. The step of the singulation of the semiconductor device 100 (step S100) may be carried out before the step of releasing the movable portion of the structure of the resonator 104 (step S90).

### [Third Modification]

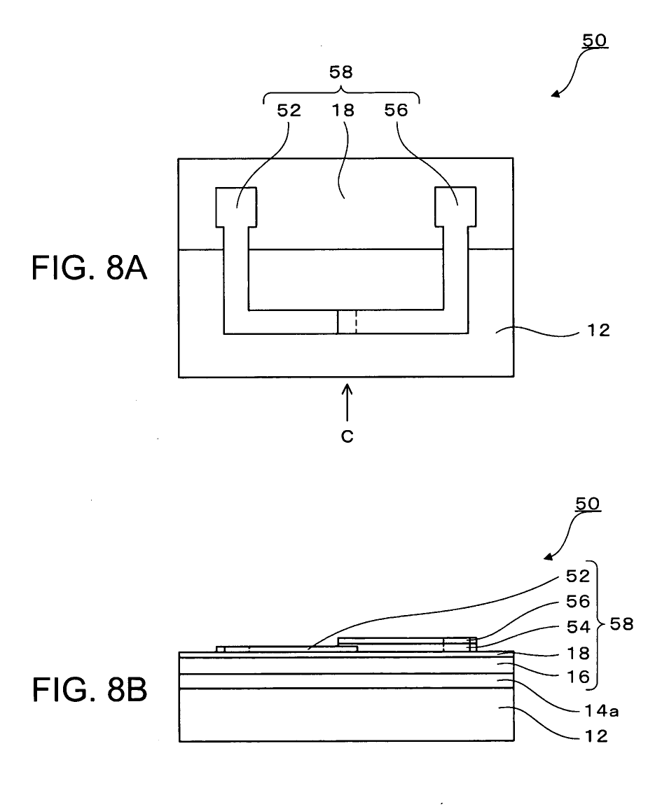

In the first embodiment, the first electrode 20, the piezoelectric layer 22, and the second electrode 24 are patterned into a reversed C-shape. However, the invention is not limited to such embodiment. The first electrode 20, the piezoelectric layer 22, and the second electrode 24 may be patterned into another shape such as a shape of letter “I,” and a shape of tuning fork. FIG. 8 is a diagram explaining the modification of the method for manufacturing a semiconductor device of the first embodiment. FIG. 8(a) is a plan view viewed from a side adjacent to a structure of a semiconductor device. FIG. 8(b) is a side view viewed from C side in FIG. 8(a). A semiconductor device 50 includes a structure 58, which is formed with a first electrode 52 patterned in a shape of letter “L,” and a piezoelectric layer 54 and a second electrode 56 that are patterned in a shape of reversed “L.” According to such configuration, the amount of expensive piezoelectric material used can be reduced while the structure is formed in the same shape as that of the first embodiment.

### [Fourth Modification]

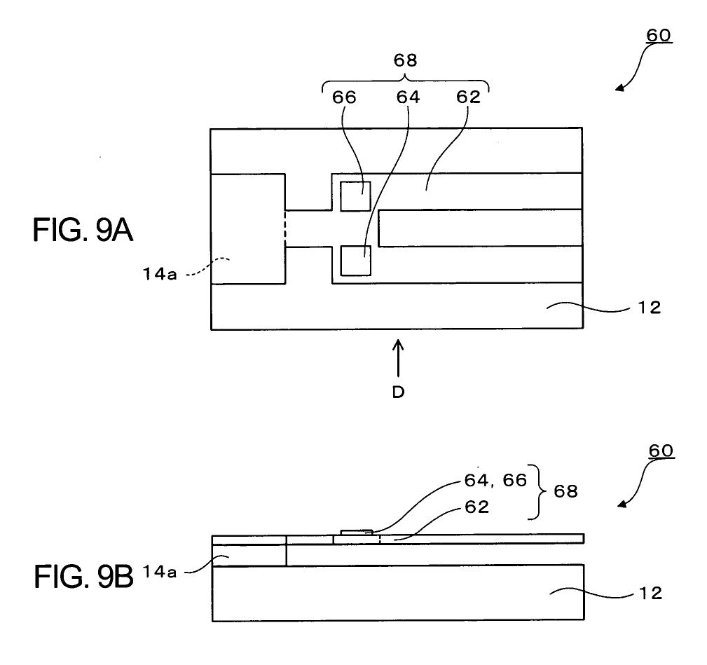

In the first embodiment, the structure 30 is formed by layering the semiconductor layer 16, the second insulation layer 18, the first electrode 20, the piezoelectric layer 22, and the second electrode 24. However, the invention is not limited to such embodiment. FIG. 9 is a diagram explaining the modification of the method for manufacturing a semiconductor device of the first embodiment. FIG. 9(a) is a plan view viewed from a side adjacent to a structure of a semiconductor device. FIG. 9(b) is a side view viewed from D side in FIG. 9(a). A semiconductor device 60 includes a structure 68 on the insulation layer 14a. The structure 68 is composed of a piezoelectric layer 62 patterned into a shape of a tuning fork, a first electrode 64 and a second electrode 66 that are formed on the piezoelectric layer 62. This configuration can downsize the structure 68, resulting in the semiconductor device 60 to be downsized. As the material of the piezoelectric layer 62, aluminum nitride is preferred. Since aluminum nitride has a high thermal conductivity and electrical insulation property, and is chemically stable, the use of aluminum nitride for the material of the piezoelectric layer 62 can provide the semiconductor device 60 having high reliability.

### [Fifth Modification]

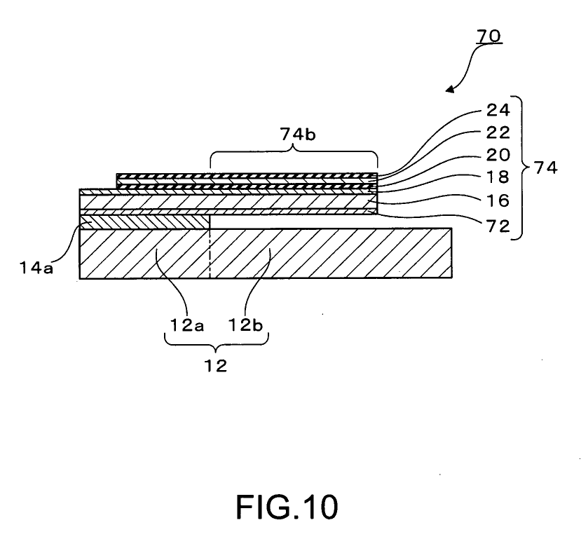

In the first embodiment, the structure 30 is formed by layering the semiconductor layer 16, the second insulation layer 18, the first electrode 20, the piezoelectric layer 22, and the second electrode 24. However, the invention is not limited to such embodiment. FIG. 10 is a diagram explaining the modification of the method for manufacturing a semiconductor device of the first embodiment. A semiconductor device 70 includes a structure 74 in which a protective layer 72 is additionally formed on a surface, facing the semiconductor substrate 12, of the semiconductor layer 16, as shown in FIG. 10. The protective layer 72 is formed on the insulation layer 14 before forming the semiconductor layer 16, and then a part of thereof is removed in forming the structure 74, for example. The protective layer 72 may be formed on the surface, facing the semiconductor substrate 12, of the semiconductor layer 16, after releasing a movable portion 74b of the structure 74. The material of the protective layer 72 is, for example, a silicon nitride film. This configuration can prevent the movable portion 74b and the semiconductor substrate 12 from being electrically conducted in the event of the movable portion 74b making contact with the semiconductor substrate 12. The protective layer 72 may be formed on a part in the surface, facing the semiconductor substrate 12, of the semiconductor layer 16, while not shown in the figure. This configuration can prevent the movable portion 74b from adhering on the semiconductor substrate 12 because the contacting area of the movable portion 74b can be reduced, in the event of the movable portion 74b making contact with the semiconductor substrate 12.

### INDUSTRIAL APPLICABILITY

The step of cutting at least a part of the insulation layer to expose the section of the insulation layer is carried out before the step of removing a portion, overlapping with the movable portion of the structure, of the insulation layer by selective etching. Accordingly, the insulation layer can be removed from not only the exposed portion of the upper surface thereof but also the exposed section, in etching the insulation layer. As a result, etching the insulation layer can be carried out in a shorter time.

A portion, overlapping with the fixing portion of the structure, of the insulation layer, i.e., the portion left, is not cut. Thus, the section of the portion is not exposed. Because of this, the insulation layer is not removed from the section of the portion left, in etching the insulation layer. As a result, the removing amount of the insulation layer in the section direction can be more readily controlled without varying the dimension and the shape of the portion left.

1. A method for manufacturing a semiconductor device, comprising:
forming a structure including a piezoelectric layer, a first electrode, and a second electrode on an insulation layer provided on a semiconductor substrate of a semiconductor device, the substrate including a semiconductor integrated circuit;
exposing a section of the insulation layer by dicing the semiconductor device;
removing the insulation layer from the exposed section by selectively etching so as to release a movable portion of the structure while a fixing portion of the structure is fixed on the insulation layer.

2. The method for manufacturing a semiconductor device according to claim 1, wherein forming the structure includes:
forming a semiconductor layer and a second insulation layer on the insulation layer in order;
forming the first electrode, the piezoelectric layer, and the second electrode on the second insulation layer in order; and
removing at least a part of a portion of each of the semiconductor layer and the second insulation layer so as to form the structure including the semiconductor layer, the second insulation layer, the first electrode, the piezoelectric layer, and the second electrode, wherein the portion does not overlap with any of the first electrode, the piezoelectric layer, and the second electrode.

3. The method for manufacturing a semiconductor device according to claim 1 further including forming the semiconductor integrated circuit on the semiconductor substrate before exposing the section of the insulation layer.

4. A method for manufacturing a semiconductor device, comprising:
forming a second insulation layer on a layered body including a semiconductor layer and an insulation layer that are layered on a semiconductor substrate of a semiconductor device, the substrate including a semiconductor integrated circuit;
forming a first electrode, a piezoelectric layer, and a second electrode on the second insulation layer in order;
removing at least a part of a portion of each of the semiconductor layer and the second insulation layer so as to form a structure including the semiconductor layer, the second insulation layer, the first electrode, the piezoelectric layer, and the second electrode, wherein the portion does not overlap with any of the first electrode, the piezoelectric layer, and the second electrode;
exposing a section of the insulation layer by dicing the semiconductor device; and
removing the insulation layer from the exposed section by selectively etching so as to release a movable portion of the structure while a fixing portion of the structure remains on the insulation layer.

5. The method for manufacturing a semiconductor device according to claim 4 further including forming the semiconductor integrated circuit on the layered body before exposing the section of the insulation layer.

6. The method for manufacturing a semiconductor device according to claim 1, wherein at least a part of the insulation layer excluding the fixing portion of the structure is cut in exposing the section of the insulation layer.

7. The method for manufacturing a semiconductor device according to claim 4, wherein the layered body includes a protective layer positioned between the insulation layer and the semiconductor layer; and a part of the protective layer is positioned in a surface of the movable portion of the structure, the surface being positioned between the semiconductor substrate and the movable portion of the structure, after removing the insulation layer by selectively etching.

8. The method for manufacturing a semiconductor device according to claim 1, further comprising forming a protective layer on a surface of the movable portion of the structure, the surface being positioned between the semiconductor substrate and the movable portion of the structure, after removing the insulation layer by selectively etching.

9. A semiconductor device manufactured by the method for manufacturing a semiconductor device according to claim 1.
